(19) United States
(12) Patent Application Publication
(10) Pub. No.: US 2026/0309767 A1
(43) Pub. Date: Oct. 8, 2026

(54) MEASUREMENT APPLICATION DEVICE AND METHOD

(71) Applicant: Rohde & Schwarz GmbH & Co. KG, München (DE)

(72) Inventor: Josef ZWACK, Pocking (DE)

(21) Appl. No.: 19/638,198

(22) Filed: Apr. 3, 2026

(30) Foreign Application Priority Data
Apr. 4, 2025 (DE) DE102025113301.8

(51) Int. Cl. G01R 31/28

(52) U.S. Cl. CPC G01R 31/28

(57) ABSTRACT

The present disclosure shows a measurement application device comprising a signal interface which is configured to capture or generate a measurement signal, a signal analysis unit which is configured to analyze the measurement signal and output a corresponding analysis result, a function selection unit which is configured to select one or more function candidates based on the analysis result, and an output unit which is configured to output the function candidates. Furthermore, the present disclosure shows a corresponding method.

### CROSS-REFERENCE TO RELATED APPLICATIONS

This application claims priority to German patent application no. DE102025113301.8, filed on Apr. 4, 2025, the entirety of which is incorporated herein by reference.

### TECHNICAL FIELD

The present disclosure relates to a measurement application device and a corresponding method.

### TECHNICAL BACKGROUND

The present disclosure is described in the following mainly in connection with devices for measurement applications, e.g., oscilloscopes. It is understood that the disclosure is not limited to such devices and can be used with all measurement application devices that capture or generate measurement signals.

Modern measurement application devices typically have a plurality of functions that a user can activate in the measurement application devices. With an increasing number of functions, the user must have the corresponding experience that allows them to use these functions, if they even know the available functions.

### SUMMARY

An object of the disclosure is therefore to simplify the control of measurement application devices.

The object is achieved by the subject matter of the independent claims.

Disclosed is:

A measurement application device comprising a signal interface which is configured to capture or generate and output a measurement signal, a signal analysis unit which is configured to analyze the measurement signal and output a corresponding analysis result, a function selection unit which is configured to select one or more function candidates based on the analysis result, and an output unit which is configured to output the function candidates.

Further, disclosed is:

A method for controlling a measurement application device, wherein the method comprises capturing or generating a measurement signal, analyzing the measurement signal and outputting a corresponding analysis result, selecting one or more function candidates based on the analysis result, and outputting the function candidates.

The present disclosure is based on the finding that in particular modern measurement application devices have a large number of functions for signal analysis and signal generation.

For inexperienced users it is difficult to use all these functions. On the one hand, a user may not know a function. On the other hand, the user may know the function but not know where or in which submenu they can find the corresponding function.

Some measurement application devices offer a user the possibility to search for functions via a search function by entering the function name. However, for this, the user must already know which function they want to find.

The present disclosure takes this finding into account and provides the measurement application device that can generate and output, or capture, a measurement signal via the signal interface. It is understood that the measurement application device can comprise multiple signal interfaces and can simultaneously generate and output, as well as capture, measurement signals via these signal interfaces.

Although not explicitly mentioned, the measurement application device can further comprise an output interface on which the captured or generated signal can be graphically displayed for a user.

The measurement application device further comprises a signal analysis unit which is configured to analyze the measurement signal and output a corresponding analysis signal. The details of such an analysis are explained in more detail in connection with the dependent claims. The analysis result can comprise, for example, information about the type of measurement signal, i.e., for example, characterize what type of signal it is or according to which standard, e.g., a communication standard, the measurement signal was generated.

For example, the signal analysis unit can perform an FFT and output the FFT signal as an analysis result. Furthermore, bus signals can be decoded and the type of bus or the content of the decoded bus signals can be output as an analysis result.

Based on the analysis result, a function selection unit selects corresponding function candidates, which can be output via an output unit, i.e., displayed to a user, for example.

The function candidates thereby represent a selection of functions which can be useful in a specific context or a specific situation. The function selection unit selects these functions based on the respective analysis result for the measurement signal. The functions can be selected, for example, specifically for a predetermined signal type, so that useful signal processing functions or signal analysis functions are suggested for the respective signal type.

With the help of the measurement application device according to the present disclosure, a user can thus efficiently and quickly access the different functions which the measurement application device provides, without having to know them in detail themselves or know how to find and activate these functions.

It is understood that the measurement application device can further comprise an input interface via which the user can select or activate a desired function candidate.

The output unit and the input interface can be, for example, the screen of the measurement application device and the input elements already present on the measurement application device. The output unit and the input interface can also be at least partially formed together as a touchscreen of the measurement application device. This also applies to the above-mentioned output interface.

It is understood that when displaying the selected function candidates, in addition to the name of a corresponding function, a short description of the function can also be displayed. Furthermore, an option can be offered to the user, for example in the form of an icon next to the corresponding function, with which they can call up a detailed description of the function.

A measurement application device according to the present disclosure can comprise any device that is used in a measurement application for capturing an input signal or for generating an output signal, or that performs additional or supporting functions in a measurement application. A measurement application device can also be implemented as a program or software application that is executed as a measurement application on a computer or processor and can communicate with other measurement application devices to perform a measurement task. A measurement application, also referred to as a measurement or test setup, can for example comprise at least one or more different measurement application devices that are used for electrical, magnetic or electromagnetic measurements, in particular on individual devices under test, also called DUT. A measurement application device according to the present disclosure can be configured to perform such electrical, magnetic or electromagnetic measurements or signal generations, for example in a measurement laboratory or in a production facility in the respective production line, on a device under test. An exemplary measurement setup can serve to qualify the individual devices under test, i.e., to check the proper electrical function of the respective devices under test.

For this purpose, measurement application devices can comprise at least one signal acquisition part for capturing electrical, magnetic or electromagnetic signals from the device under test and/or at least one signal generation part for generating electrical, magnetic or electromagnetic signals that can be supplied to the device under test. Such a signal acquisition part can contain, for example, but is not limited to, a front-end stage for receiving, filtering, attenuating or amplifying electrical signals. The signal generation part can comprise, for example, but is not limited to, corresponding signal generators, amplifiers and filters. In embodiments, signal acquisition via the signal acquisition part is carried out in a wired or contact-based manner. For this purpose, a corresponding measurement probe can be connected to the measurement application device via a corresponding cable. Likewise, in embodiments, signal generation and output via the signal generation part is carried out in a wired or contact-based manner. For this purpose, a corresponding signal output probe can be connected to the measurement application device via a corresponding cable, or the signal is output directly via the cable, e.g., to a device under test. In further embodiments, signal acquisition can be carried out contactlessly, e.g., via corresponding antennas, also called OTA or over-the-air. In further embodiments, signal generation and output can be carried out contactlessly, e.g., via corresponding antennas, also called OTA or over-the-air. A combination of contact-based signal acquisition, contactless signal acquisition, contact-based signal generation and output, and contactless signal generation and output is also possible.

Furthermore, measurement application devices can comprise, during signal acquisition, a signal processing unit that processes the acquired signals. The processing can include converting the acquired signals from analog to digital signals or vice versa and any other type of digital signal processing, for example the conversion of time domain signals to frequency domain signals.

The measurement application devices can also comprise a user interface to display the acquired signals to the user and to allow the user to control the measurement application devices. Of course, a housing can be provided that comprises the elements of the measurement application device. It is understood that additional elements such as a power supply circuit and communication interfaces can be provided.

A measurement application device can be a standalone device that can be operated without further elements in a measurement application to perform tests on a device under test. Of course, communication capabilities can also be provided to connect the measurement application device with other measurement application devices.

A measurement application device can be, for example, a signal recording device such as an oscilloscope, in particular a digital oscilloscope, a spectrum analyzer or a vector network analyzer. A measurement application device can also comprise a signal generation device, e.g., a signal generator, in particular a so-called “arbitrary signal generator”, also referred to as an “arbitrary waveform generator”, or a vector signal generator. Further possible measurement application devices include devices such as calibration standards or measurement probe tips.

Of course, at least some of the possible functions, such as signal recording and signal generation, can be combined in a single measurement application device.

In embodiments, the measurement application device can comprise pure data acquisition devices that are capable of capturing an input signal and transmitting the captured input signal as a digital input signal to a corresponding data memory or application server. Such pure data acquisition devices do not necessarily comprise a user interface or a display. Instead, such pure data acquisition devices can be remotely controlled, e.g., via a corresponding data connection such as a network interface or a USB interface. The same applies to pure signal generation devices that can generate an output signal without having a user interface or configuration input devices. Instead, such signal generation devices can be operated remotely via a data connection.

The signal analysis unit can comprise a dedicated processing element or be provided as part of such an element, for example as a processor unit, microcontroller, field-programmable gate array (FPGA), complex programmable logic device (CPLD), application specific integrated circuit (ASIC) or the like. A corresponding program or configuration can be provided to implement the required functionality. The signal analysis unit can also be at least partially provided as a non-transitory computer program product that contains computer-readable instructions that can be executed by a processing element. In a further embodiment, the signal analysis unit can be integrated as an additional function or method into the firmware or the operating system of a processing element already present in the respective application, wherein the corresponding computer-readable instructions are provided. Such computer-readable instructions can be stored in a memory that is coupled to or integrated into the processing element. The processing element can load and execute the computer-readable instructions from the memory. The same applies to all other elements, units or functions that are disclosed here as part of the measurement application device and the method, such as the function selection unit and the control unit.

Furthermore, it is understood that any required supporting or additional hardware, such as a power supply circuit and a clock generator circuit, can be provided.

In general, any computer program or computer program product disclosed here is to be understood as a non-transitory computer program product. Furthermore, any method disclosed herein is to be understood as an automated or computer-implemented method.

Further embodiments and developments emerge from the dependent claims and from the description with reference to the figures. In particular, all embodiments mentioned herein can be combined with one another in any order or number, unless individual features are mutually exclusive. In particular, the dependent claims of one claim category can also be further developed according to another claim category.

In an embodiment, which can be combined with all embodiments mentioned herein, the signal analysis unit can comprise a first trained algorithm of machine learning, which is configured to receive the measurement signal and output a corresponding analysis result.

The term “algorithm of machine learning” is to be understood as any algorithm that can be adapted or trained with corresponding training data to generate the analysis result from the measurement signal. Such algorithms can also be called AI or artificial intelligence algorithms. It is understood that within the scope of this disclosure, not only so-called neural networks, but also other types of adaptable, i.e., trainable, algorithms can be used.

Corresponding algorithms can comprise, for example, so-called transformer models or transformer networks, which are trained to generate the analysis result from the waveform of the measurement signal. However, any other suitable algorithm of machine learning can also be used.

The first trained algorithm can be trained, for example, with waveforms or images of signals and corresponding sets of analysis results. Such data can be compiled, for example, by a manufacturer of the measurement application device or collected during operation of the measurement application devices and used to train the first trained algorithm.

In a further embodiment, which can be combined with all embodiments mentioned herein, the signal analysis unit can further be coupled to a control unit of the measurement application device, and can be configured to receive a current configuration of the measurement application device from the control unit and to determine the analysis result at least partially based on the current configuration.

The signal analysis unit can determine the analysis result not only based on the first algorithm. Alternatively or additionally, the signal analysis unit can also use a current configuration of the measurement application device to determine the analysis result.

The current configuration can provide indications of the current context in which the measurement application device is being used. For example, a user of a measurement application device for signal acquisition may have already specified that a PAM-N, e.g., a PAM-4 signal, is to be measured and have made corresponding settings on the measurement application device.

The signal analysis unit can use this information to generate the current measurement context and thus the analysis result. The analysis result can, but does not have to, be based on the actual measurement signal. Rather, the analysis result can also be based on information about the measurement signal that is provided to the signal analysis unit.

In an embodiment, which can be combined with all further embodiments, the current configuration can also be provided directly to the function selection unit as the analysis result.

In yet another embodiment, which can be combined with all embodiments mentioned herein, the signal analysis unit can further be configured to determine the analysis result at least partially based on at least one specific sub-range of the measurement signal.

Particularly when analyzing signals of an electrical device to be tested, also called DUT or device under test, it can be important to examine certain specific sub-ranges of the measurement signal. Such sub-ranges can be, for example, ranges that comprise a signal peak, no signal, or a specific signal shape. The specific sub-range consequently characterizes a sub-range of the measurement signal that is particularly relevant for the respective measurement task. In particular, the specific sub-range can be very small or short compared to the entire measurement signal.

If the analysis result is generated based on such a specific sub-range of the measurement signal, the subsequent selection of the function candidates can take into account the properties of this particularly relevant sub-range of the measurement signal.

In yet a further embodiment, which can be combined with all embodiments mentioned herein, the signal analysis unit can further comprise an identification unit, which can be configured to determine the specific sub-range of the measurement signal.

The identification unit can determine the specific sub-range based on the pure measurement signal. Additionally or alternatively, the identification unit can take into account the current configuration of the measurement application device when determining the specific sub-range.

For example, the identification unit can perform so-called “time gating”, in which certain time ranges are automatically “cut out” or filtered for further processing. For example, a settling behavior can also be detected and the specific sub-range begin after the settling. For this purpose, e.g., time constants can be automatically determined.

In embodiments, the identification unit can detect noisy signal components or open inputs and hide such signal sections or deliberately identify them depending on the task. For example, an increased standard deviation or variance can be detected by the identification unit.

For example, the identification unit can form an average value for the signal values of the measurement signal and mark signal values that deviate from the average value by more than a predetermined threshold value as a specific range.

In an embodiment, which can be combined with all further embodiments, the identification unit can comprise an “algorithm of machine learning” which is trained to identify the specific ranges in measurement signals. The explanations regarding the further “algorithms of machine learning” disclosed herein apply analogously.

In an embodiment, which can be combined with all embodiments mentioned herein, the function selection unit can further comprise a second trained algorithm of machine learning, which is configured to select the function candidates based on the analysis result.

The above explanations regarding the first “algorithm of machine learning” apply analogously to the second “algorithm of machine learning”.

The term “algorithm of machine learning” is therefore to be understood for the second algorithm as any algorithm that can be adapted or trained with corresponding training data to determine the function candidates from the analysis result. Such algorithms can also be called AI or artificial intelligence algorithms. It is understood that within the scope of this disclosure, not only so-called neural networks, but also other types of adaptable, i.e., trainable, algorithms can be used.

Corresponding algorithms can comprise, for example, so-called transformer models, also called transformer networks, or so-called large language models, also called LLMs, which are trained to determine corresponding function candidates from the analysis result. However, any other suitable algorithm of machine learning can also be used.

The second trained algorithm can be trained, for example, based on manuals, so-called application notes, and further documents relating to the measurement application device, which explain which functions the measurement application device comprises for examining or generating a respective measurement signal.

Particularly when using an LLM as the second algorithm, the function selection unit can generate a corresponding prompt, which is fed to the corresponding LLM. Such a prompt can be based on the analysis result and comprise a request to the LLM to identify corresponding function candidates. The LLM can also be used within the scope of a so-called RAG pipeline, also retrieval-augmented generation pipeline. In such an embodiment, for example, together with the analysis result, a selection of possible functions can be passed to the LLM. The LLM can be instructed via the corresponding prompt to use only, or at least preferably, functions from the passed list.

In yet another embodiment, which can be combined with all embodiments mentioned herein, the second trained algorithm can be trained during use of the measurement application device based on functions of the measurement application device selected by a user.

An “algorithm of machine learning” generates outputs in each case based on the training data with which it was trained. Even if these comprise, for example, a statistically relevant magnitude, a user's behavior in detail can deviate from such training data.

In an embodiment, consequently, the behavior of the user who operates the measurement application device can be observed. If the user uses functions other than those that were output as function candidates, this can be logged. Such deviations from the proposed function candidates can then be used for further training of the second algorithm.

In an embodiment, which can be combined with all embodiments disclosed herein, the second algorithm can be updated, i.e., a new version of the second algorithm can be provided in the measurement application device. The update can be performed, for example, automatically whenever a newly trained or retrained algorithm is available.

It can be provided that the logs regarding deviating use of the measurement application device are bundled, for example centrally at a manufacturer of the respective measurement application device, and used for central training of the second algorithm. It can further be provided to ask users of the measurement application device for permission before the logs are transmitted to the manufacturer.

In an embodiment, which can be combined with all embodiments disclosed herein, each of the used “algorithms of machine learning” can be provided externally to the respective measurement application device, in particular in a corresponding server. The measurement application device can comprise a corresponding communication interface to communicate with the externally provided algorithm.

### BRIEF DESCRIPTION OF THE DRAWINGS

The present disclosure is explained in more detail below using the exemplary embodiments indicated in the schematic figures of the drawings.

FIG. 1 shows a block diagram of an embodiment of a measurement application device according to the present disclosure;

FIG. 2 shows a block diagram of a further embodiment of a measurement application device according to the present disclosure

FIG. 3 shows a block diagram of yet another embodiment of a measurement application device according to the present disclosure;

FIG. 4 shows a block diagram of a further embodiment of a measurement application device according to the present disclosure;

FIG. 5 shows a flow chart of an embodiment of a method according to the present disclosure;

FIG. 6 shows a block diagram of an embodiment of an oscilloscope, which can serve as a measurement application device according to the present disclosure; and

FIG. 7 shows a block diagram of an embodiment of a further oscilloscope, which can serve as a measurement application device according to the present disclosure.

In all figures, functionally identical elements and devices—unless otherwise specified—have been provided with similar reference numerals, which are the same at least in the two least significant digits (ones and tens).

### DETAILED DESCRIPTION OF THE FIGURES

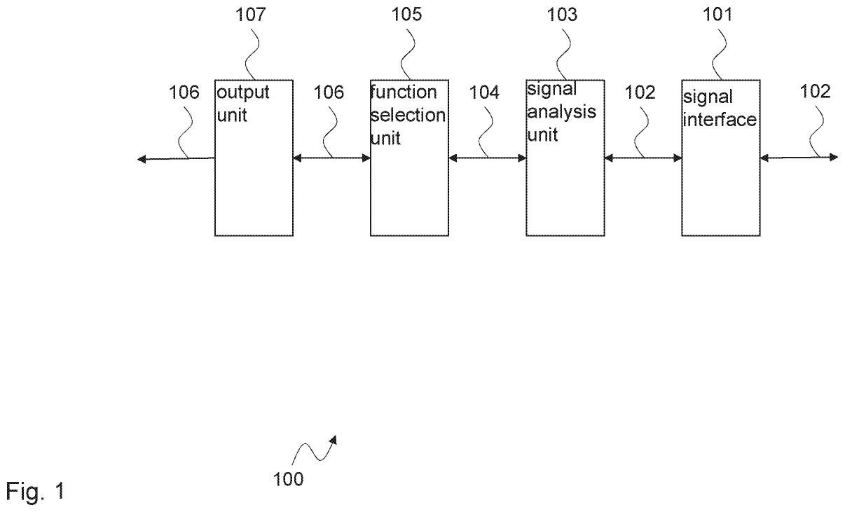

FIG. 1 shows a measurement application device 100. The measurement application device 100 comprises a signal interface 101, which is coupled to a signal analysis unit 103. The signal analysis unit 103 is coupled to a function selection unit 105, which in turn is coupled to an output unit 107. The signal interface 101 generates a measurement signal 102 and outputs it, or receives the measurement signal 102. The measurement signal 102 is forwarded to the signal analysis unit 103, which analyzes the measurement signal 102 and transmits a corresponding analysis result 104 to the function selection unit 105. The function selection unit 105 determines one or more function candidates 106 based on the analysis result 104. These function candidates 106 are output via the output unit 107. The explanations regarding other embodiments of the measurement application device disclosed herein apply analogously to the measurement application device 100.

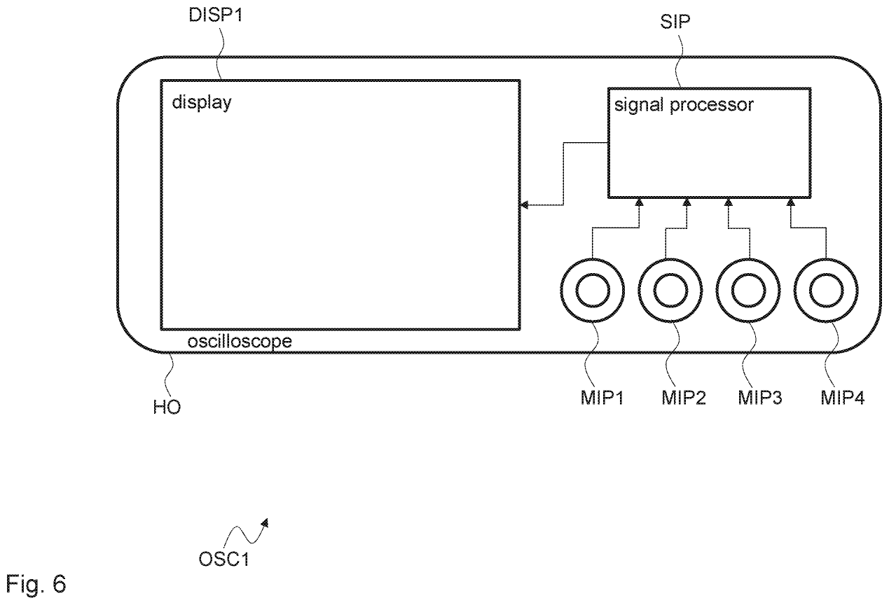

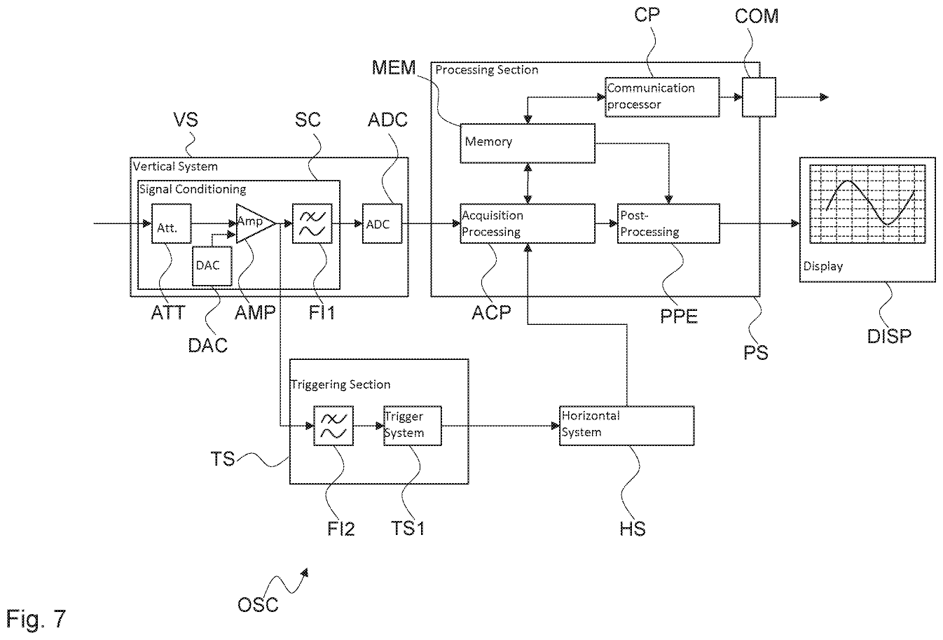

Although not shown separately, it is understood that the measurement application device 100 can comprise further components for signal generation and signal acquisition and signal evaluation, such as shown in FIGS. 6 and 7.

In embodiments, the functions of the measurement application device 100 can be at least partially integrated into other elements present in the measurement application device 100 for other functions. For example, a control unit of such a measurement application device can perform the functions of the signal analysis unit 103 and the function selection unit 105, while a screen of the measurement application device 100 can implement the output unit 107.

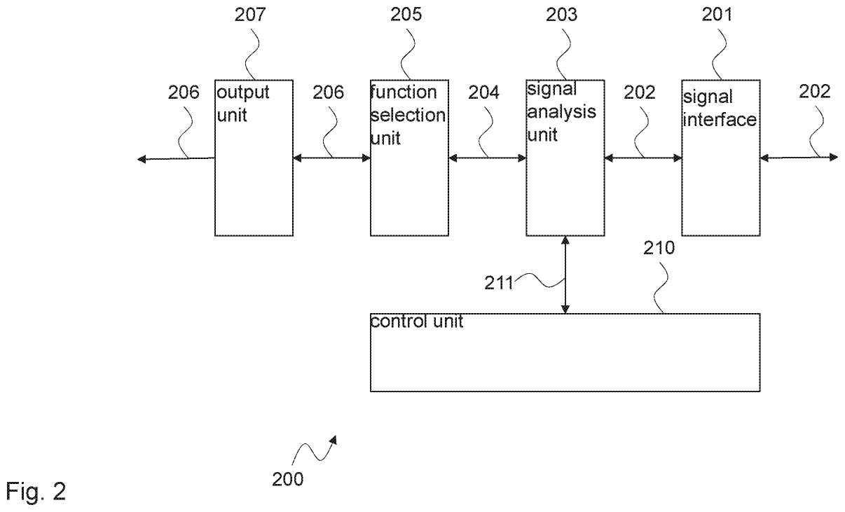

FIG. 2 shows a measurement application device 200. The measurement application device 200 is based on the measurement application device 100. Therefore, the measurement application device 200 comprises a signal interface 201, which is coupled to a signal analysis unit 203. The signal analysis unit 203 is coupled to a function selection unit 205, which in turn is coupled to an output unit 207. The signal interface 201 generates a measurement signal 202 and outputs it, or receives the measurement signal 202. The measurement signal 202 is forwarded to the signal analysis unit 203, which analyzes the measurement signal 202 and transmits a corresponding analysis result 204 to the function selection unit 205. The function selection unit 205 determines one or more function candidates 206 based on the analysis result 204. These function candidates 206 are output via the output unit 207. The explanations regarding other embodiments of the measurement application device disclosed herein apply analogously to the measurement application device 200.

The measurement application device 200 further comprises a control unit 210, which is coupled to the signal analysis unit 203. The control unit 210 can be a central control unit of the measurement application device 200, which is intended to perform general control tasks in the measurement application device 200. Such a control unit 210 can, for example, comprise a processor that executes corresponding firmware or an operating system, which enables the display of data on a screen and the capture of user input, as well as corresponding control of the measurement application device 200.

The signal analysis unit 203 can receive or retrieve a current configuration 211 of the measurement application device 200 from the control unit 210. The signal analysis unit 203 can then determine the analysis result 204 at least partially based on this current configuration 211.

As already explained above, the current configuration 211 can comprise, for example, information about which settings a user has made on the measurement application device 200 for signal generation or signal acquisition. Such information can relate, for example, to frequency ranges, signal levels, or signal types.

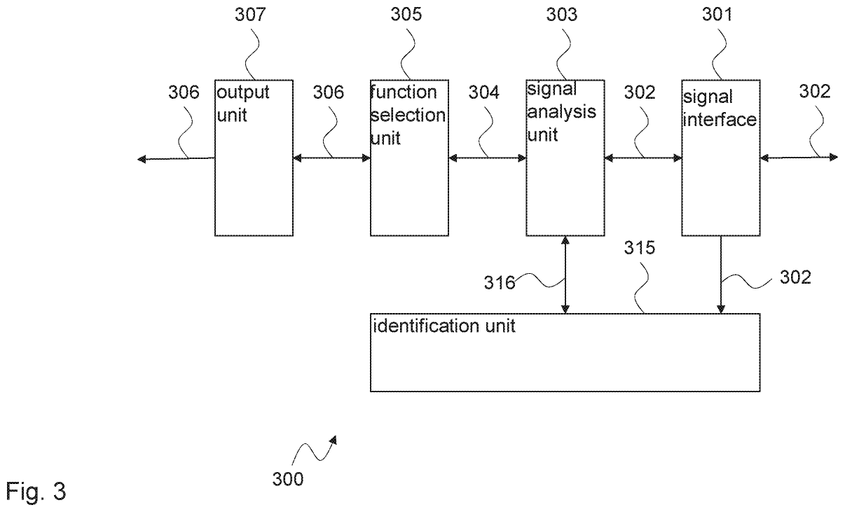

FIG. 3 shows a measurement application device 300. The measurement application device 300 is based on the measurement application device 100. Therefore, the measurement application device 300 comprises a signal interface 301, which is coupled to a signal analysis unit 303. The signal analysis unit 303 is coupled to a function selection unit 305, which in turn is coupled to an output unit 307. The signal interface 301 generates a measurement signal 302 and outputs it, or receives the measurement signal 302. The measurement signal 302 is forwarded to the signal analysis unit 303, which analyzes the measurement signal 302 and transmits a corresponding analysis result 304 to the function selection unit 305. The function selection unit 305 determines one or more function candidates 306 based on the analysis result 304. These function candidates 306 are output via the output unit 307. The explanations regarding other embodiments of the measurement application device disclosed herein apply analogously to the measurement application device 300.

The measurement application device 300 comprises an identification unit 315, which is coupled to the signal interface 301 to obtain the measurement signal 302. In embodiments, the identification unit 315 can also obtain the measurement signal 302 from another unit, e.g., from the signal analysis unit 303.

The identification unit 315 determines at least one specific sub-range 316 of the measurement signal 302 for the signal analysis unit 303. The signal analysis unit 303 can thus determine the analysis result 304 at least partially based on the at least one specific sub-range 316 of the measurement signal 302.

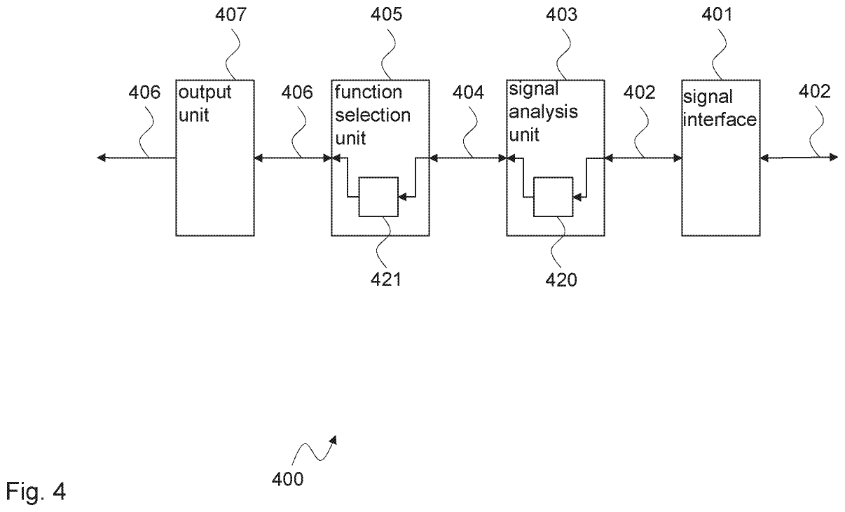

FIG. 4 shows a measurement application device 400. The measurement application device 400 is based on the measurement application device 100. Therefore, the measurement application device 400 comprises a signal interface 401, which is coupled to a signal analysis unit 403. The signal analysis unit 403 is coupled to a function selection unit 405, which in turn is coupled to an output unit 407. The signal interface 401 generates a measurement signal 402 and outputs it, or receives the measurement signal 402. The measurement signal 402 is forwarded to the signal analysis unit 403, which analyzes the measurement signal 402 and transmits a corresponding analysis result 404 to the function selection unit 405. The function selection unit 405 determines one or more function candidates 406 based on the analysis result 404. These function candidates 406 are output via the output unit 407. The explanations regarding other embodiments of the measurement application device disclosed herein apply analogously to the measurement application device 400.

In the measurement application device 400, the signal analysis unit 403 comprises a first trained algorithm 420 of machine learning. Furthermore, the function selection unit 405 comprises a second trained algorithm 421 of machine learning. In embodiments, the first trained algorithm 420 can be omitted, or the second trained algorithm 421 can be omitted. The two algorithms 420, 421 are thus to be considered optional.

The first trained algorithm 420 is configured to receive the measurement signal 402 and output a corresponding analysis result 404. The second trained algorithm 421 is configured to select the function candidates 406 based on the analysis result 404.

In particular, the second trained algorithm 421 can be further trained during use of the measurement application device 400 based on functions of the measurement application device 400 selected by a user, even during operation.

For easier understanding, the reference numerals for FIGS. 1-4 are retained as a reference in the following description.

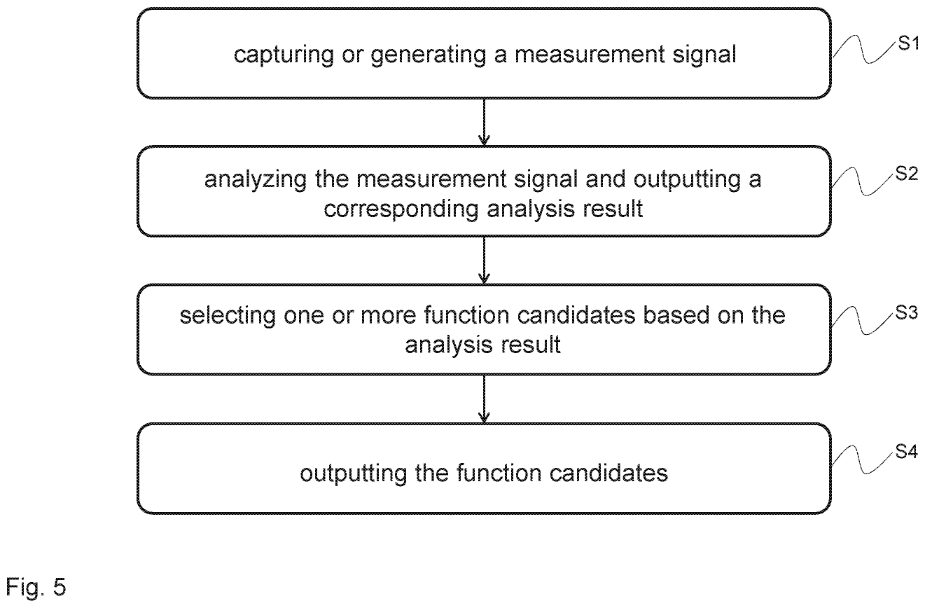

FIG. 5 shows a method for controlling a measurement application device 100, 200, 300, 400, wherein the method comprises: capturing or generating S1 a measurement signal 102, 202, 302, 402, analyzing S2 the measurement signal 102, 202, 302, 402 and outputting a corresponding analysis result 104, 204, 304, 404, selecting S3 one or more function candidates 106, 206, 306, 406 based on the analysis result 104, 204, 304, 404, and outputting S4 the function candidates 106, 206, 306, 406.

The analyzing of the measurement signal 102, 202, 302, 402 and the outputting of a corresponding analysis result 104, 204, 304, 404 can comprise receiving a current configuration 211 of the measurement application device 100, 200, 300, 400, e.g., from the control unit 210, and determining the analysis result 104, 204, 304, 404 at least partially based on the current configuration 211.

The method can further comprise determining a specific sub-range 316 of the measurement signal 102, 202, 302, 402. The analyzing of the measurement signal 102, 202, 302, 402 and the outputting of a corresponding analysis result 104, 204, 304, 404 can comprise determining the analysis result 104, 204, 304, 404 at least partially based on the at least one specific sub-range 316 of the measurement signal 102, 202, 302, 402.

The analyzing of the measurement signal 102, 202, 302, 402 and outputting of the corresponding analysis result 104, 204, 304, 404 can be performed with a first trained algorithm 420 of machine learning. This can be configured to receive the measurement signal 102, 202, 302, 402 and output a corresponding analysis result 104, 204, 304, 404.

Furthermore, the selecting of one or more function candidates 106, 206, 306, 406 can be performed with a second trained algorithm 421 of machine learning, which is configured to select the function candidates 106, 206, 306, 406 based on the analysis result 104, 204, 304, 404. The second trained algorithm 421 can be further trained during use of the measurement application device 100, 200, 300, 400 based on functions of the measurement application device 100, 200, 300, 400 selected by a user.

FIG. 6 shows a block diagram of an oscilloscope OSC1, which can comprise an implementation of a measurement application device according to the present disclosure.

The oscilloscope OSC1 comprises a housing HO that accommodates four measurement inputs MIP1, MIP2, MIP3, MIP4, which are connected to a signal processor SIP to process measured signals. The signal processor SIP is connected to a display DISP1 to display the measured signals to a user.

Although not explicitly shown, it is understood that the oscilloscope OSC1 can also comprise signal outputs. Such signal outputs can serve, for example, for outputting calibration signals. Such calibration signals allow the calibration of the measurement setup before performing measurements. The process of calibration and correction of measurement signals based on the calibration can also be referred to as “de-embedding” and can comprise applying corresponding algorithms to the generated or measured signals.

In the oscilloscope OSC1, the signal processor SIP or an additional processing element can perform or implement the functions of the signal analysis unit and the function selection unit according to the present disclosure. Of course, a communication interface for communication with other measurement application devices can be provided in the oscilloscope OSC1.

FIG. 7 shows a block diagram of an oscilloscope OSC, which can be an implementation of a measurement application device according to the present disclosure. The oscilloscope OSC is implemented as a digital oscilloscope. It is noted, however, that the present disclosure can also be implemented with any other type of oscilloscope.

The oscilloscope OSC comprises, by way of example, five general sections: the vertical system VS, the triggering section TS, the horizontal system HS, the processing section PS, and the display DISP. It is understood that the division into five general sections represents a logical division and does not restrict the placement and implementation of the elements of the oscilloscope OSC in any way.

The vertical system VS serves mainly to offset, attenuate and amplify a signal to be acquired. The signal can be modified, for example, so that it fits into the available display area of the display DISP or has a vertical size configured by a user.

For this purpose, the vertical system VS comprises a signal conditioning section SC with an attenuator ATT and a digital-to-analog converter DAC, which are connected to an amplifier AMP. The amplifier AMP is connected to a filter FI1, which in the example shown is provided as a low-pass filter. The vertical system VS also comprises an analog-to-digital converter ADC, which receives the output of the filter FI1 and converts the received analog signal into a digital signal.

The attenuator ATT and the amplifier AMP serve to adapt the amplitude of the signal to be acquired to the operating range of the analog-to-digital converter ADC. The digital-to-analog converter DAC serves to modify the direct current component of the input signal to be acquired so that it fits into the operating range of the analog-to-digital converter ADC. The filter FI1 serves to filter out unwanted high-frequency components of the signal to be acquired.

The triggering section TS operates with the signal provided by the amplifier AMP. The triggering section TS comprises a filter FI2, which in this embodiment is implemented as a low-pass filter. The filter FI2 is connected to a trigger system TS1.

The triggering section TS serves to capture predefined signal events and enables the horizontal system HS, for example, to display a stable view of a repeated waveform or simply to display waveform sections that contain the respective signal event. It is understood that the predefined signal event can be configured by a user via a user input of the oscilloscope OSC.

Possible predefined signal events can include, but are not limited to, when the signal exceeds a predefined trigger threshold in a predefined direction, i.e., with a rising or falling edge. Such a trigger condition is also referred to as edge trigger. Another trigger condition is referred to as “glitch triggering” and triggers when a pulse occurs in the signal to be acquired whose width is greater or less than a predefined time.

In order to enable an exact match of the trigger signal with the waveform displayed on the display DISP, a common time base can be provided for the analog-to-digital converter ADC and the trigger system TS1.

It is understood that, although not explicitly shown, the trigger system TS1 can comprise at least one of the following components: configurable voltage comparators for setting the trigger thresholds, fixed voltage sources for setting the required edge, corresponding logic gates such as an XOR gate and flip-flops for generating the trigger signal.

The triggering section TS is provided by way of example as an analog triggering section. It is understood that the oscilloscope OSC can also be equipped with a digital triggering section. Such a digital triggering section does not operate with the analog signal provided by the amplifier AMP, but with the digital signal provided by the analog-to-digital converter ADC.

A digital triggering section can comprise a processing element, such as a processor, a DSP, a CPLD, an ASIC, or an FPGA, to implement digital algorithms for detecting a valid trigger signal.

The horizontal system HS is connected to the output of the trigger system TS1 and serves mainly to position and scale the signal to be acquired horizontally on the display DISP.

The oscilloscope OSC further comprises a processing section PS, which implements digital signal processing and data storage for the oscilloscope. The processing section PS comprises an acquisition processing element ACP, which is connected to the output of the analog-to-digital converter ADC and the output of the horizontal system HS, as well as to a memory MEM and a post processing element PPE.

The acquisition processing element ACP manages the acquisition of digital data from the analog-to-digital converter ADC and the storage of the data in the memory MEM. The acquisition processing element ACP can, for example, comprise a processing element that comprises a digital interface to the analog-to-digital converter ADC and a digital interface to the memory MEM. The processing element can, for example, comprise a microcontroller, a DSP, a CPLD, an ASIC, or an FPGA with corresponding interfaces. In a microcontroller or DSP, the functionality of the acquisition processing element ACP can be implemented as computer-readable instructions that are executed by a CPU. In a CPLD or FPGA, the functionality of the acquisition processing element ACP can be configured in the CPLD or FPGA instead of having software executed by a processor.

The processing section PS further comprises a communication processor CP and a communication interface COM.

The communication processor CP can be a device that manages data transfer to and from the oscilloscope OSC. The communication interface COM can be designed for any suitable communication standard, such as Ethernet, WIFI, Bluetooth, NFC, an infrared communication standard, and a visible light-based communication standard.

The communication processor CP is connected to the memory MEM and can use the memory MEM to store and retrieve data.

Of course, the communication processor CP can also be connected to any other element of the oscilloscope OSC to retrieve device data or to provide device data, e.g., received from a management server.

The post processing element PPE can be controlled by the acquisition processing element ACP and can access the memory MEM to retrieve data to be displayed on the display DISP. The post processing element PPE can prepare the data stored in the memory MEM so that the display DISP can display the data to a user, for example as a waveform. The post processing element PPE can also implement analysis functions such as cursors, waveform measurements, histograms, or mathematical functions.

The display DISP controls all aspects of signal representation for a user and can, although not explicitly shown, comprise any component required to receive data to be displayed and to control a display device to display the data as desired.

It is understood that the oscilloscope OSC, even if not shown, can comprise a user interface via which a user can interact with the oscilloscope OSC. Such a user interface can comprise dedicated input elements such as, for example, buttons and switches. At least partially, the user interface can also be provided as a touch-sensitive display device.

In the oscilloscope OSC, one of the processing elements, also referred to as computing element, in the processing section PS or an additional processing element can perform the function of the signal analysis unit and the function selection unit according to the present disclosure.

It is understood that all elements of the oscilloscope OSC that perform digital data processing can be provided as dedicated elements. Alternatively, at least some of the functions described above can be implemented in a single hardware element, such as a microcontroller, DSP, CPLD, or FPGA. In general, the logical functions described above can be implemented in any suitable hardware element of the oscilloscope OSC and do not necessarily have to be divided into the various sections described above.

The processes, methods, or algorithms disclosed herein can be transferred to or implemented by a computing unit, a controller, or a computer. These can comprise any existing programmable electronic control unit or dedicated electronic control unit. Likewise, the processes, methods, or algorithms can be stored as data and instructions that can be executed by a controller or computer in many forms, including, but not limited to, information permanently stored on non-writable storage media such as ROM devices, and information alterably stored on writable storage media such as floppy disks, magnetic tapes, CDs, RAM memory, and other magnetic and optical media. The processes, methods, or algorithms can also be implemented in a software-executable object. Alternatively, the processes, methods, or algorithms can be embedded wholly or partially in suitable hardware components such as application specific integrated circuits (ASICs), field-programmable gate arrays (FPGAs), state machines, controllers, or other hardware components or devices, or a combination of hardware, software, and firmware components.

Although exemplary embodiments are described above, it is understood that these embodiments do not cover all possible forms of implementation of the present disclosure covered by the claims. The terms used in the specification serve the purpose of description and not limitation, and it is understood that various changes can be made without departing from the spirit and scope of the disclosure. As previously described, the features of various embodiments can be combined to form further embodiments of the invention that may not be explicitly described or illustrated. While various embodiments may be described as advantageous or preferred over other embodiments or implementations of the prior art with respect to one or more desired characteristics, those skilled in the art recognize that one or more characteristics or features can be altered in favor of desired overall system characteristics, which depend on the specific application and implementation. These characteristics can include, but are not necessarily limited to, cost, strength, durability, life cycle cost, marketability, appearance, packaging, size, serviceability, weight, manufacturability, ease of assembly, etc. Thus, to the extent embodiments are described as less desirable than other embodiments or implementations of the prior art with respect to specific characteristics, these embodiments nonetheless fall within the scope of the disclosure and may be desirable for specific applications.

With respect to the processes, systems, methods, heuristics, etc. described herein, it is understood that, although the steps of such processes etc. have been described in a particular order, such processes can also be performed in an order different than that described herein. Likewise, it is understood that certain steps can be performed simultaneously, that other steps can be added, or that certain steps described herein can be omitted. In other words, the descriptions of the processes herein serve to illustrate certain embodiments and should in no way be construed as limiting the claims.

In summary, it is understood that the disclosed subject matter can be modified and varied without departing from the scope of the present disclosure.

All terms used in the claims are intended to be given their broadest reasonable interpretation and their plain meanings, as understood by those familiar with the technologies described herein, unless expressly stated otherwise. In particular, the use of singular articles, such as “a,” “the,” “said,” etc., should be read to include one or more of the indicated elements, unless a claim expressly states the contrary.

LIST OF REFERENCE NUMERALS

| | |
|---|---|
| 100, 200, 300, 400 | measurement application device |
| 101. 201, 301, 401 | signal interface |
| 102, 202, 302, 402 | measurement signal |
| 103, 203, 303, 403 | signal analysis unit |
| 104, 204, 304, 404 | analysis result |
| 105, 205, 305, 405 | function selection unit |
| 106, 206, 306, 406 | function candidates |
| 107, 207, 307, 407 | output unit |
| 210 | control unit |
| 211 | current configuration |
| 315 | identification unit |
| 316 | specific sub-range |
| 420 | first trained algorithm |
| 421 | second trained algorithm |
| S1-S4 | method steps |
| OSC1 | oscilloscope |
| HO | housing |
| MIP1, MIP2, MIP3, MIP4 | measurement input |
| SIP | signal processor |
| DISP1 | display |
| OSC | oscilloscope |
| VS | vertical system |
| SC | signal conditioning section |
| ATT | attenuator |
| DAC | digital-to-analog converter |
| AMP | amplifier |
| FI1 | filter |
| ADC | analog-to-digital converter |
| TS | triggering section |
| AMP2 | amplifier |
| FI2 | filter |
| TS1 | trigger system |
| HS | horizontal system |
| PS | processing section |
| ACP | acquisition processing element |
| MEM | memory |
| PPE | post processing element |
| DISP | display |

1. A measurement application device comprising:
a signal interface configured to capture or generate a measurement signal;
a signal analysis unit configured to analyze the measurement signal and output a corresponding analysis result;
a function selection unit configured to select one or more function candidates based on the analysis result; and
an output unit configured to output the function candidates.

2. The measurement application device according to claim 1, wherein the signal analysis unit comprises a first trained algorithm of machine learning configured to receive the measurement signal and output a corresponding analysis result.

3. The measurement application device according to claim 1, wherein the signal analysis unit is further coupled to a control unit of the measurement application device, and is configured to receive a current configuration of the measurement application device from the control unit and to determine the analysis result at least partially based on the current configuration.

4. The measurement application device according to claim 1, wherein the signal analysis unit is further configured to determine the analysis result at least partially based on at least one specific sub-range of the measurement signal.

5. The measurement application device according to claim 4, wherein the signal analysis unit further comprises an identification unit configured to determine the at least one specific sub-range of the measurement signal.

6. The measurement application device according to claim 1, wherein the function selection unit further comprises a second trained algorithm of machine learning configured to select the function candidates based on the analysis result.

7. The measurement application device according to claim 6, wherein the second trained algorithm is trained during use of the measurement application device based on functions of the measurement application device selected by a user.

8. A method for controlling a measurement application device, wherein the method comprises:
capturing or generating a measurement signal;
analyzing the measurement signal and outputting a corresponding analysis result;
selecting one or more function candidates based on the analysis result; and
outputting the function candidates.

9. The method according to claim 8, wherein the analyzing of the measurement signal and outputting of the corresponding analysis result is performed with a first trained algorithm of machine learning configured to receive the measurement signal and output a corresponding analysis result.

10. The method according to claim 8, wherein the analyzing of the measurement signal and outputting of a corresponding analysis result comprises:
receiving a current configuration of the measurement application device; and
determining the analysis result at least partially based on the current configuration.

11. The method according to claim 8, wherein the analyzing of the measurement signal and outputting of a corresponding analysis result comprises determining the analysis result at least partially based on at least one specific sub-range of the measurement signal.

12. The method according to claim 11, further comprising determining the specific sub-range of the measurement signal.

13. The method according to claim 8, wherein the selecting of one or more function candidates is performed with a second trained algorithm of machine learning configured to select the function candidates based on the analysis result.

14. The method according to claim 13, wherein the second trained algorithm is trained during use of the measurement application device based on functions of the measurement application device selected by a user.

15. The method according to claim 8, wherein the method is executed by a processing element that executes computer-readable instructions that when executed by the processing element cause the processing element to execute the method.

16. The measurement application device according to claim 1, further comprising a processing element configured to execute computer-readable instructions that when executed by the processing element cause the processing element to execute at least one of the functions of the signal analysis unit and the functions of the function selection unit.
